(19) United States
(12) Patent Application Publication
(10) Pub. No.: US 2005/0012089 A1
(43) Pub. Date: Jan. 20, 2005

(54) Metal organic chemical vapor deposition and atomic layer deposition of metal oxynitride and metal silicon oxynitride

(76) Inventors: Yoshihide Senzaki, Aptos, CA (US); Sang-In Lee, Cupertino, CA (US)

Correspondence Address: DORSEY & WHITNEY LLP;INTELLECTUAL PROPERTY DEPARTMENT, 4 EMBARCADERO CENTER, SUITE 3400, SAN FRANCISCO, CA, 94111, US

(21) Appl. No.: 10/504,704

(22) PCT Filed: Jul. 16, 2003
(86) PCT No.: PCT/US03/22060

Related U.S. Application Data
(60) Provisional application No. 60/396,744, filed on Jul. 19, 2002.

(51) Int. Cl. H01L 35/24

(52) U.S. Cl. 257/40

(57) ABSTRACT

The invention is directed to gate and capacitor dielectrics for use in making advanced high-g stack structures. According to the invention, a metal alkyamide, wherein the metal is halfnium (Hf) or zirconium (Zr) is used in a MOCVD or ALD process to create metal oxynitride or metal silicon oxynitride dielectric layers. In general, the metal oxynitride or metal silicon oxynitride layers are positioned between a silicon substrate and a doped polycrystalline silicone (Poly Si) layer.

### BACKGROUND OF THE INVENTION

1. Field of the Invention

The present invention relates generally to the field of gate and capacitor dielectrics. More specifically, the present invention relates to metal organic chemical vapor deposition (“MOCVD”) and atomic layer deposition (“ALD”) of halfnium oxynitride (Hf—O—N), zirconium oxynitride (Zr—O—N), halfnium silicon oxynitride (Hf—Si—O—N), and/or zirconium silicon oxynitride (Zr—Si—O—N) layers to form gate and capacitor dielectrics.

2. Description Of Related Art

As the scale of electronic components decrease, the pressure increases to find alternative gate and capacitor dielectric materials for silicon dioxide (SiO₂). Halfnium based dielectrics were considered a promising candidate due to a high dielectric constant (k˜20) and good thermal stability when placed in contact with a silicon (Si) substrate. However, undesired interfacial silicon oxide (SiOₓ) formation during post-deposition thermal treatment occurs.

Recently, halfnium oxynitride and halfnium silicon oxynitride, deposited by reactive sputtering, were reported to have better electrical properties and thermal stability than non-nitrogen containing counterparts, i.e. halfnium dioxide (HfO₂) and halfnium silicon oxide (Hf—Si—O). See M. R. Visokay et al., Properties of Hf-Based Oixde and Oxynitride Thin Films, Proceedings of 2002 AVS 3^{rd} International Conference on Microelectronics and Interfaces,p. 127 (Feb. 11-14, 2002).

The use of metal amide for the MOCVD of high-k gate and capacitor dielectrics is known. See Senazaki et al., MOCVD of High-K Dielectrics, Tantalum Nitride and Copper, Adv. Mater. Opt. Electrn., vol. 10, p. 93 (2000). However, the MOCVD or ALD of halfnium oxynitride and halfnium silicon oxynitride has not been reported.

### SUMMARY OF THE INVENTION

The invention is directed to gate and capacitor dielectrics for use in making advanced high-k stack structures. According to the invention, a halfnium alkylamide is used in a MOCVD or ALD process to create halfnium oxynitride and/or halfnium silicon oxynitride dielectric layers. Alternatively, zirconium alkyamide is used in a MOCVD or ALD process to create zirconium oxynitride and/or zirconium silicon oxynitride. In general, the metal oxynitride or metal silicon oxynitride is positioned between a silicon substrate and a doped polycrystalline silicone (Poly Si) layers

According to the invention, the metal oxynitride layers are produced by reacting a metal alkylamide with an oxidant and a nitrogen source. Similarly, the metal silicon oxynitride layers are produced by reacting, a metal alkylamide with a silicon tetraalkylamide, an oxidant and a nitrogen source.

These dielectrics may be employed to produce high-k stacked structures. For example, in one embodiment, one or more metal oxynitride or metal silicon oxynitride layers are positioned intermediate between a silicon substrate and Poly Si layer. Alternatively, in another embodiment, the metal oxynitride or metal silicon oxynitride layers surround metal oxide layers to form a more complex dielectric intermediate between a silicon substrate and a Poly Si layer.

From the production point of view, MOCVD and ALD are more desirable processes than a sputtering process which requires a high vacuum system. Using MOCVD and ALD, metal oxynitride and metal silicon oxynitride can be deposited at relatively low temperatures (below 500° C.) and at approximately 1 Torr—which is much more practical for device production.

### BRIEF DESCRIPTION OF DRAWINGS

The invention will be described in detail in the following description of preferred embodiments with reference to the following figures wherein:

FIG. 1 is a schematic of a first high-k stack structure made in accordance with the present invention.

FIG. 2 is a schematic of a second high-g stack structure made in accordance with the present invention.

### DETAILED DESCRIPTION OF PREFERRED EMBODIMENTS

The invention is directed to gate and capacitor dielectrics for use in making advanced high-g stack structures using an MOCVD or ALD process. According to the invention, a metal alkylamide.(wherein the metal is Hf or Zr) is used to create halfnium oxynitride, zirconium oxynitride, halfnium silicon oxynitride, or zirconium silicon oxynitride dielectric layers.

From the production point of view, MOCVD and ALD are more desirable processes than asputtering which requires a high vacuum system. Using MOCVD and ALD, metal oxynitride and metal silicon oxynitride layers can be deposited at relatively low temperatures (below 500° C.) and at approximately 1 Torr. Preferably, the deposition is performed at temperatures ranging from 100° C. to 500° C and more preferably 200° C. to 500° C.

As appreciated by those in the art, MOCVD is a process wherein a metal organic compound and one or more other reactants are introduced, in a gaseous or liquid form, into a reaction and reacted within the reaction chamber to form the desired precipitate, e.g., a metal oxide or metal nitride or metal oxynitride. The precipitate drops down to form a layer on the base material which is generally a material, e.g. silicon, whose surface is able to bind the precipitate.

As also appreciated by those in the art, ALD is an alternative to MOCVD. In ALD, a metal organic compound is introduced, in a gaseous state, into a reaction chamber. The reaction chamber contains a base material, e.g., silicon, whose surface is able to chemically or physically bind the metal organic compound. This generates an atomic layer, or mono-layer, of metal organic compound on the surface of the base material. Excess metal organic compound is then purged from the chamber. Next, one or more reactants are introduced into the chamber in a gaseous state. The reactants react with the metal organic mono-layer and convert it into a more desirable material, e.g., a metal oxide or metal nitride or metal oxynitride. The process is then repeated until the desired layer thickness is achieved.

ALD has several advantages relative to MOCVD, namely, operability at comparatively low temperatures, and the ability to produce conformal thin film layers on non-planar substrates. It is possible using ALD to control film thickness on an atomic scale and, thereby, “nano-engineer” complex thin films.

In the instant invention, metal oxynitride or metal silicon oxynitride dielectrics (wherein the metal is Hf or Zr) are generated using an MOCVD or ALD process. Specifically, metal oxynitride layers are produced by reacting a metal alkylamide with an oxidant and a nitrogen source. Similarly, metal silicon oxynitride layers are produced by reacting a metal alkylamide with a silicon source, an oxidant and a nitrogen source.

A number of metal alkyamides may be used in the invention. Metal alkylamides are generally characterized by the presence of a metal group bonded through a single bond to one or more alkyl substituted nitrogen atoms.

Suitable metal alkylamides include compounds conforming to the following formula or mixture thereof:
M(NR¹R²)ₙ (1)
wherein R¹ and R², independently, are selected from the group consisting of substituted or unsubstituted linear, branched, cyclic and aromatic alkyls. Preferably, n is 4. Preferably, R¹ and R² are, individually, a C₁-C₆ alkyl. M is selected from Hf or Zr.

The nitrogen source is preferably ammonia. However, it should be recognized that other nitrogen sources may be utilized with roughly equivalent effect, such as hydrazine (H₂NNH₂), primary, secondary and tertiary alkyl amines, alkyl hydrazine, and atomic nitrogen (N).

The oxidant is not limited. However, preferred oxidants are selected from the group consisting of oxygen (O₂), ozone (O₃), nitrous oxide (N₂O), hydrogen peroxide (H₂0₂), and atomic oxygen (O).

The silicon source is preferably, but not limited to, silicon alkylamide, silane, disilane, dichlorosilane, SiCl₄, SiHCl₃, Si₂Cl₄, alkylsilane, aminosilane, Me₃Si—N═N—SiMe₃. Suitable silicon alkyamides for use in the invention include those defined by the following formula:
Si(NRR⁶₂)₄ (3)
wherein R, R⁶( are selected from the group consisting of substituted or unsubstituted linear, branched, cyclic and aromatic alkyls. Preferably, R⁶ is a C₁-C₆ alkyl.

By way of illustration, to form the halfnium oxynitride product, one of the following reactions may be performed using either the MOCVD or ALD process:
Hf(NR¹R²)₄+O₂+NH₃→Hf—O—N+by product (4)
or
(R³—N═)ₘHf(NR⁴R⁵)ₚ+O₂+NH₃→Hf—O—N+by product (5)
In other words, when the halfnium alkylamide is exposed to an oxidant and a nitrogen source, a halfnium oxynitride precipitate is formed.

Similarly, to form the halfnium silicon oxynitride product, one of the following reactions may be performed using either the MOCVD or ALD process:
Hf(NR¹R²)₄+Si(NRR⁶₂)₄+O₂+NH₃→Hf—O—N+by product (6)
or
(R³—N═)ₘHf(NR⁴R⁵)ₚ+Si(NR⁶₂)₄+O₂+NH₃→Hf—O—N+by product (7)
In other words, when the halfnium alkylamide is exposed to a silicon alkylamide, an oxidant, and a nitrogen source, a halfnium silicon oxynitride precipitate is formed.

A number of high-k stack structures can be made using the gate and capacitor dielectric materials of the invention. For example, halfnium oxynitride or halfnium silicon oxynitride layers may be sandwiched between a silicon wafer and layers of Poly Si. Once again, this is done using either the MOCVD or ALD process.

Alternatively, halfnium oxynitride or halfnium silicon oxynitride layers may surround halfnium oxide (higher k of 20˜25) layers to form a dielectric intermediate. The dielectric intermediate is then, in turn, sandwiched between a silicon wafer and layers of Poly Si.

These embodiments are visually illustrated in the attached figures.

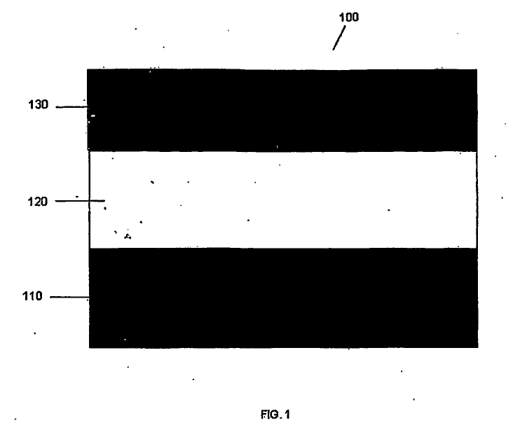

FIG. 1 is a schematic of a first high-k stack structure 100 made in accordance with the present invention. In FIG. 1, a silicon substrate 110 is coated with an intermediate layer 120 of halfnium oxynitride or halfnium silicon oxynitride. The intermediate layer, in turn is coated with an uppermost layer 130 of Poly Si. The intermediate layer 120 provides a high dielectric material between the highly conductive uppermost Poly Si layer 130 and relatively less conductive silicon substrate 110.

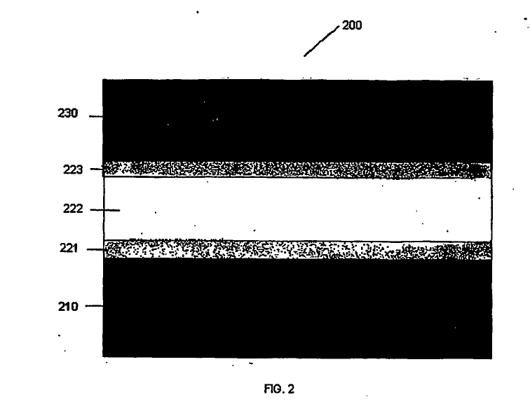

FIG. 2 is a schematic of a second high-k stack structure 200 made in accordance with the present invention. In FIG. 2, a silicon substrate 210 is coated with a first intermediate layer 221 of halfnium oxynitride or halfnium silicon oxynitride. The first intermediate layer is then coated with a second intermediate layer 222 of halfnium oxide. The second intermediate layer 222 is then coated with a third intermediate layer 223 which, like the first intermediate layer 221 is composed of halfnium oxynitride or halfnium silicon oxynitride. Finally, the third intermediate layer 223 is coated with an uppermost layer 230 of Poly Si. The three intermediate layers, 221, 222 and 223, combine to form a high dielectric material between the highly conductive uppermost Poly Si layer 230 and the relatively less conductive silicon substrate 210.

Having described preferred embodiments and examples of novel dielectric materials and processes of forming the same (which are intended to be illustrative and not limiting), it is noted that modifications and variations can be made by persons skilled in the art in light of the above teachings. It is therefore to be understood that changes may be made in the particular embodiments of the invention disclosed which are within the scope and spirit of the invention as defined by the appended claims.

Having thus described the invention with the details and particularity required by the patent laws, what is claimed and desired protected by Letters Patent is set forth in the appended claims.

1. A metal organic chemical vapor deposition (MOCVD) or atomic layer deposition (ALD) method of forming a dielectric, wherein the dielectric is formed by reacting a metal alkylamide with a nitrogen source, an oxidant and, optionally, a silicon source, and wherein the metal in the metal alkyamide is either halfnium or zirconium.
